(19) United States
(12) Patent Application Publication
(10) Pub. No.: US 2014/0218844 A1
(43) Pub. Date: Aug. 7, 2014

(54) Rack for Electronic Devices

(71) Applicant: Ching-Chao Tseng, Changhua County (TW)

(72) Inventor: Ching-Chao Tseng, Changhua County (TW)

(21) Appl. No.: 13/761,429

(22) Filed: Feb. 7, 2013

(51) Int. Cl. H05K 7/14

(52) U.S. Cl. CPC H05K 7/14
USPC 361/679.01

(57) ABSTRACT

A rack includes a frame, two locking portions and a power unit. The frame includes multiple links and the two locking portions are located on two correspondent links or formed on extension portions of the links. The power unit is located corresponding to one of the locking portions and located in the frame, or the power unit is parallel to one of the locking portions and located in the frame. The power unit has at least one power cable and multiple power modules which are respectively connected to one side of the power unit and exposed from the power unit. Each of the power modules is connected to one of the at least one power cable. The two sides of the electronic device are fixed to the locking portions. The power cable and the transmission line of the electronic device are connected to the power unit.

### BACKGROUND OF THE INVENTION

(1) Field of the Invention

The present invention relates to a rack, and more particularly, to a rack cooperated with a longitudinal power unit.

(2) Description of the Prior Art

The personal computers such as table-top computers, laptops and panel computers are used widely in the modern society, however, along with the development of the electronic technology, the boundary-less electronic commerce is formed and replaces the local and small scale of business. Special design servos such as firewalls, switches, and routers are developed to meet the demands of the electronic business.

In order to store and process the large numbers of data, the storage units and processing units are established, which mean multiple servos are installed into one rack so as to save space and to easily manage the servos. The appearance of the servos are designed according to a standard wherein the height is measured by U (1U=1.75 inches=44.45 mm). There are several standard servos such as 1U, 2U, 3U, 4U, 5U, 6U and 7U. The size of the rack is measured by the common industry standard.

Generally, there are multiple power distribution units (PDU) are installed to the inside of the rack so as to be respectively and electrically connected to the modularized electronic devices. However, the PDU and the electronic device is connected to each other one by one, so that many cables are exposed when multiple electronic devices are installed to the rack, and this makes the management and maintenance to be difficult. Besides, the PDUs in the market are usually installed to the top or bottom of the rack, some the electronic devices cannot reach the remote position of the PDUs. The cables of the electronic devices have to go over other electronic devices and the messy cables waste time when in maintenance.

The present invention intends to provide a rack which improves the shortcomings of the conventional rack.

### SUMMARY OF THE INVENTION

The present invention relates to a rack and comprises a frame, two locking portions and a power unit. The frame includes multiple links and the two locking portions are located on two correspondent links or formed on extension portions of the links. The power unit is located corresponding to one of the locking portions and located in the frame, or the power unit is parallel to one of the locking portions and located in the frame. The power unit has at least one power cable and multiple power modules which are respectively connected to one side of the power unit and exposed from the power unit. Each of the power modules is connected to one of the at least one power cable. When at least one electronic device is installed to the rack, the two sides of the at least one electronic device are fixed to the locking portions. At least one power cable and at least one transmission line of the at least one electronic device are connected to the power unit.

Preferably, the power unit is perpendicular to an outside of one of the locking portions.

Preferably, the power unit is a power distribution unit (PDU).

Preferably, the power unit has at least one transmission line so as to remote control power output from the power unit.

Preferably, the power unit has at least one signal connection module so as to connect at least one electronic device with exterior internet.

Preferably, each of the power modules meets requirements of IEC 60320 of International Electrotechnical Commission.

Preferably, each of the power modules meets requirements of C13 and C14 coupler unit or C19 and C20 coupler unit of International Electrotechnical Commission.

Preferably, the frame meets requirements of EIA-310-D of Electronic Industries Association (EIA).

Preferably, a gap between two of the power modules is 44.45 mm.

The longitudinal arrangement of the power unit is benefit for being connected from the electronic devices that are installed to the rack to improve the cable management of the electronic devices.

The cables of the electronic devices are well managed is benefit for heat removal.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is an exploded view to show the frame and the power unit of the rack of the present invention;

FIG. 2 is a perspective view to show the rack with the power unit of the present invention;

FIG. 3 is a perspective view to show the power unit of the present invention, and

FIG. 4 is a rear end view of the rack of the present invention wherein multiple electronic devices are installed to the rack.

### DETAILED DESCRIPTION OF THE PREFERRED EMBODIMENT

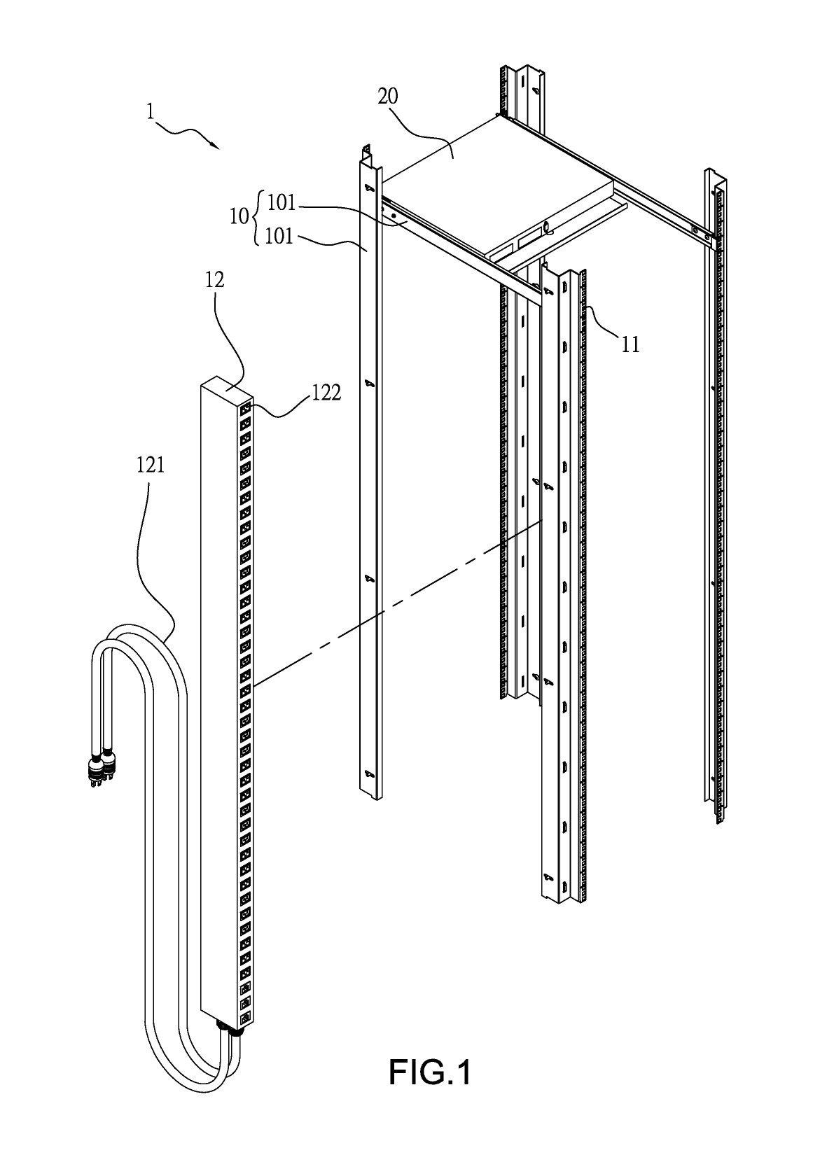

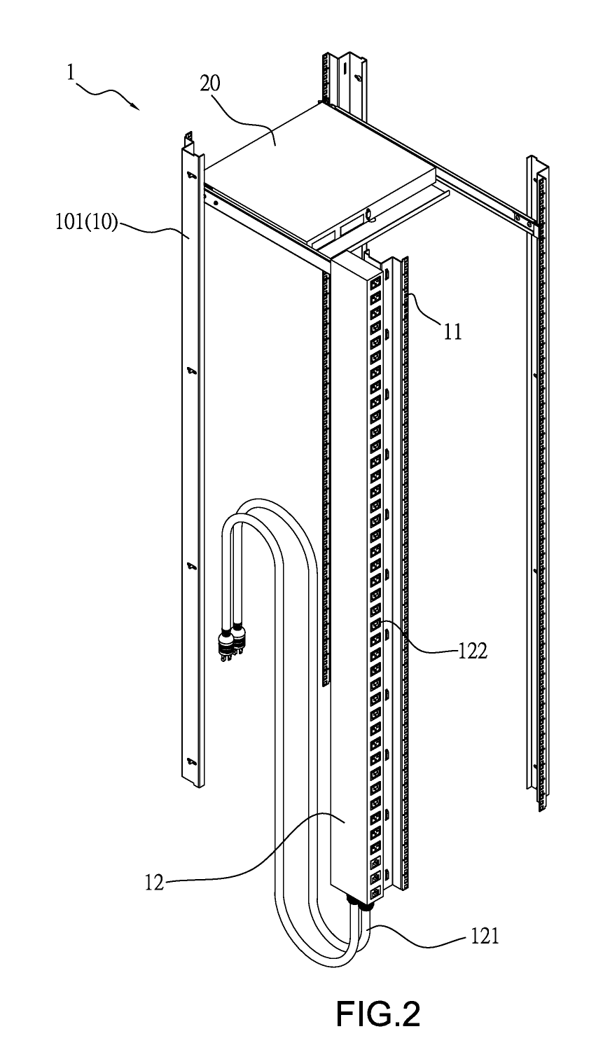

Referring to FIGS. 1 and 2, the rack 1 of the present invention comprises a frame 10, two locking portions 11 and a power unit 12. The frame 10 comprises multiple links 101 so that the electronic devices 20 are installed to the rack 1 by the frame 10. The two locking portions 11 are located on two correspondent links 101 or formed on extension portions of the links 101. The power unit 12 is located corresponding to one of the locking portions 11 and located close to the locking portion 11. In practical use, the power unit 12 is located beside the locking portion 11 in the frame 10, that is to say, the power unit 12 is parallel to one of the locking portions 11 so that the users can easily access the cables and the electronic devices 20. In another embodiment, the power unit 12 is perpendicular to the outside of one of the locking portions 11 and located in the frame 10. That is to say, the power unit 12 is installed beside the locking portion 11 and the related cables and the signal transmission lines are easily hidden in the frame 10.

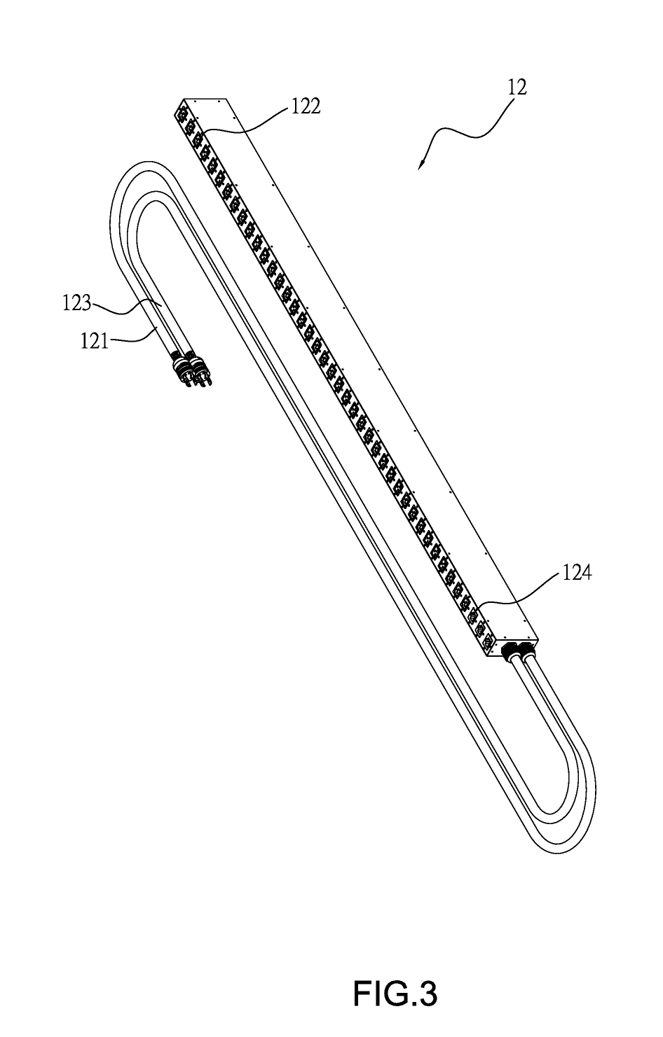

As shown in FIG. 3, the power unit 12 has at least one power cable 121, multiple power modules 122, at least one signal transmission line 123 and multiple signal connection modules 124. The power unit 12 is a power distribution unit (PDU). The users can control the power modules 122 or the signal connection modules 124 of the power unit 12 from remote place. The use of the PDU is known to skilled persons and will not be described here. The power modules 122 are receptacles or smart receptacles which control the related coefficients. The signal connection modules 124 are network jacks or signal transmission related jacks. It is noted that each of the power modules 122 meets requirements of IEC 60320 of International Electrotechnical Commission, and the requirements of C13 and C14 coupler unit or C19 and C20 coupler unit of International Electrotechnical Commission. In order to cooperate with the heights of the standard electronic devices 20, the gap between two of the power modules 122 is 44.45 mm (1U). The gap can be adjusted according to practical needs.

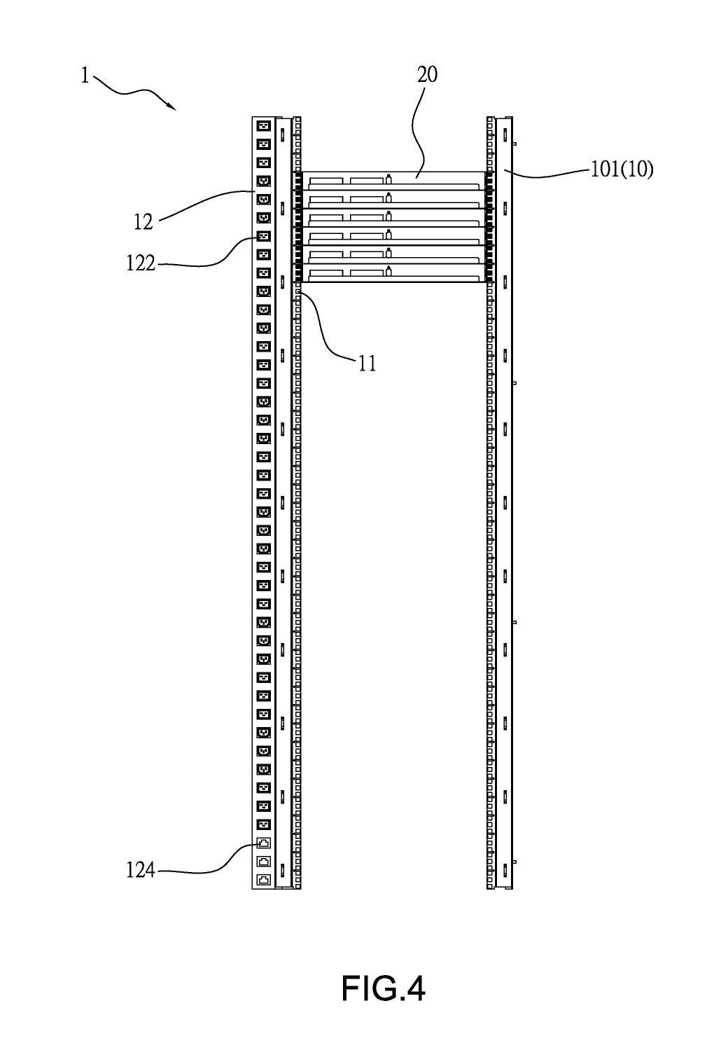

As shown in FIG. 4, the frame 10 meets requirements of EIA-310-D of Electronic Industries Association (EIA). When the electronic devices 20 are installed to the rack 1 one by one, and secured by the locking portions 11. After the electronic devices 20 are securely installed, the rack 1 is then turned the rear side to face the uses and the power cables 121 and signal transmission lines 123 of the electronic devices 20 can be easily connected to the corresponding power modules 122 or the signal connection modules 124. The connection can be done easily and quickly. The cable management is improved so as to increase the efficiency of heat removal.

While we have shown and described the embodiment in accordance with the present invention, it should be clear to those skilled in the art that further embodiments may be made without departing from the scope of the present invention.

What is claimed is:

1. A rack comprising:
a frame having multiple links;
two locking portions located on two correspondent links or being formed on extension portions of the links, and
a power unit located corresponding to one of the locking portions and located in the frame, or the power unit being parallel to one of the locking portions and connected to the frame, the power unit having at least one power cable, multiple power modules respectively connected to one side of the power unit and exposed from the power unit, each of the power modules connected to one of the at least one power cable.

2. The rack as claimed in claim 1, wherein the power unit is perpendicular to an outside of one of the locking portions.

3. The rack as claimed in claim 1, wherein the power unit is a power distribution unit (PDU).

4. The rack as claimed in claim 1, wherein the power unit has at least one transmission line so as to remote control power output from the power unit.

5. The rack as claimed in claim 4, wherein the power unit has at least one signal connection module so as to connect at least one electronic device with exterior internet.

6. The rack as claimed in claim 1, wherein each of the power modules meets requirements of IEC 60320 of International Electrotechnical Commission.

7. The rack as claimed in claim 1, wherein each of the power modules meets requirements of C13 and C14 coupler unit or C19 and C20 coupler unit of International Electrotechnical Commission.

8. The rack as claimed in claim 1, wherein the frame meets requirements of EIA-310-D of Electronic Industries Association (EIA).

9. The rack as claimed in claim 1, wherein a gap between two of the power modules is 44.45 mm.
